(19) United States
(12) Patent Application Publication
(10) Pub. No.: US 2013/0051117 A1
(43) Pub. Date: Feb. 28, 2013

(54) INTEGRATED CIRCUIT WITH VERTICALLY INTEGRATED PASSIVE VARIABLE RESISTANCE MEMORY AND METHOD FOR MAKING THE SAME

(71) Applicants: William G. En, Milpitas, CA (US); Don R. Weiss, Fort Collins, CO (US)

(72) Inventors: William G. En, Milpitas, CA (US); Don R. Weiss, Fort Collins, CO (US)

(73) Assignee: ADVANCED MICRO DEVICES, INC., Sunnyvale, CA (US)

(21) Appl. No.: 13/216,610

(22) Filed: Aug. 24, 2011

(51) Int. Cl. G11C 11/21; H01L 47/00; G06F 17/50; H01L 21/20

(52) U.S. Cl. 365/148; 438/382; 257/4; 716/129; 257/E47.001; 257/E21.09

(57) ABSTRACT

In one example, an integrated circuit includes memory control logic (e.g., CMOS logic circuit) and passive variable resistance memory disposed above the memory control logic. The passive variable resistance memory, also known as resistive non-volatile memory, may be for example memristors, phase-change memory, or magnetoresistive memory. Each memory cell of the passive variable resistance memory is electrically connected to the memory control logic through at least one vertical interconnect accesses (vias). For example, the operation (e.g., write/read) of each passive variable resistance memory cell is controlled by the memory control logic. The integrated circuit may also include processor logic operatively coupled to the memory control logic.

### CROSS-REFERENCE TO RELATED APPLICATION

This application is related to co-pending application having docket number 00100.10.0562, filed on even date, having inventors William En et al., titled “INTEGRATED CIRCUIT WITH BACKSIDE PASSIVE VARIABLE RESISTANCE MEMORY AND METHOD FOR MAKING THE SAME”, owned by instant assignee; and co-pending application having docket number 00100.10.0563, filed on even date, having inventors William En et al., titled “INTEGRATED CIRCUIT WITH FACE-TO-FACE BONDED PASSIVE VARIABLE RESISTANCE MEMORY AND METHOD FOR MAKING THE SAME”, owned by instant assignee.

### BACKGROUND OF THE DISCLOSURE

The disclosure relates generally to an integrated circuit and to a method for making the same.

Dynamic random access memory (DRAM) and flash memory are two dominant memory technologies generally accepted to be nearing the end of their scaling lifetime, and the search is on for a replacement that can scale beyond DRAM and flash memory, while maintaining low latency and energy efficiency. Passive variable resistance memory, also known as resistive non-volatile memory, is emerging as a ubiquitous next generation of flash replacement technology (FRT). Passive variable resistance memory includes but is not limited to memristors, phase-change memory, and magnetoresistive memory (e.g., spin-torque transfer magnetoresistive memory). The key behind the passive variable resistance memory is storing state in the form of resistance instead of charge.

Similar to DRAM and flash memory, passive variable resistance memory may be used as on-chip memory integrated with processors, such as central processing units (CPUs) or graphic processing units (GPUs), in the forms of cache memory and/or main memory. It is known to place the passive variable resistance memory either laterally on the same die of the processor or on a separate die connected laterally to the processor die through a circuit board. Either implementation, however, has issues with cost and distance of the memory to where it is needed on the processor. As the passive variable resistance memory and the processor are laterally arranged, the die area and packaging size may be increased, and the memory access may be slowed down due to the relative long lateral connection distance.

Accordingly, there exists a need for an improved integrated circuit with passive variable resistance memory and a method for making the same.

### BRIEF DESCRIPTION OF THE DRAWINGS

The embodiments will be more readily understood in view of the following description when accompanied by the below figures and wherein like reference numerals represent like elements, wherein:

FIG. 1 is a block diagram illustrating one example of an apparatus including a processor having an integrated circuit with vertically integrated passive variable resistance memory;

FIG. 2 is an illustration of one example of a wafer including a plurality of integrated circuit dies with vertically integrated passive variable resistance memory;

FIG. 3 is a cross-sectional view illustration of one example of the integrated circuit with vertically integrated passive variable resistance memory shown in FIG. 1;

FIG. 4 is a flowchart illustrating one example of a method for making the integrated circuit with vertically integrated passive variable resistance memory shown in FIG. 3;

FIG. 5 is a cross-sectional view illustration of one example of the integrated circuit with vertically integrated passive variable resistance memory shown in FIG. 3 in accordance with one embodiment set forth in the disclosure;

FIG. 6 is a flowchart illustrating one example of a method for making the integrated circuit with vertically integrated passive variable resistance memory shown in FIG. 5 in accordance with one embodiment set forth in the disclosure;

FIGS. 7 and 8 are top and cross-sectional view illustrations, respectively, of one example of a memristor as a vertically integrated passive variable resistance memory cell of an integrated circuit with vertically integrated passive variable resistance memory in accordance with one embodiment set forth in the disclosure; and

FIG. 9 is a flowchart illustrating one example of a method for making an integrated circuit with vertically integrated passive variable resistance memory in accordance with one embodiment set forth in the disclosure.

### DETAILED DESCRIPTION OF THE PREFERRED EMBODIMENTS

Briefly, in one example, an integrated circuit includes memory control logic (e.g., CMOS logic circuit) and vertically integrated passive variable resistance memory disposed above the memory control logic. The passive variable resistance memory, also known as resistive non-volatile memory, may be for example memristors, phase-change memory, or magnetoresistive memory. Each memory cell of the passive variable resistance memory is electrically connected to the memory control logic through at least one vertical interconnect accesses (vias). For example, the operation (e.g., write/read) of each passive variable resistance memory cell is controlled by the memory control logic. The integrated circuit may also include processor logic operatively coupled to the memory control logic.

Among other advantages, the method for making the integrated circuit with vertically integrated passive variable resistance memory provides a simple and inexpensive way to integrate the next generation of FRT (e.g., passive variable resistance memory) with the existing processors to improve the processor performance. This method allows for the FRT processing to be done after the CMOS logic devices (e.g., processor logic and/or memory control logic) are fabricated to avoid integration problems and to separate the FRT material contamination from the CMOS logic devices. In addition, compared with known integration solutions, the vertically integrated passive variable resistance memory eliminates any die area increase and enables faster memory access by both reducing the connection distance and allowing for the increased number of parallel connections. Other advantages will be recognized by those of ordinary skill in the art.

In one example, after forming the memory control logic, the method forms a dielectric layer above the memory control logic. The method then forms a lower electrode layer above the dielectric layer. For example, the method may pattern the lower electrode layer to form a plurality of word lines for the passive variable resistance memory. Each word line is electrically connected to the memory control logic through at least one of the plurality of vias. The method then forms a memory layer above the lower electrode layer. For example, the method may pattern the memory layer to form a plurality of memory regions for each of the plurality of passive variable resistance memory cells. The method then forms an upper electrode layer above the memory layer. For example, the method may pattern the upper electrode layer to form a plurality of bit lines for the passive variable resistance memory. Each bit line is electrically connected to the memory control logic through at least one of the plurality of vias. Each memory region of the memory layer is disposed at a place where each word line and bit line overlap, and passive variable resistance memory cell may be part of a crosspoint array. In this example, the resistance of each memory region changes based on a first electrical signal applied to the plurality of word lines and a second electrical signal applied to the plurality of bit lines by the memory control logic through the plurality of vias.

In another example, the method forms multiple layers of passive variable resistance memory cells. For example, the method may form a second dielectric layer above the first upper electrode layer to separate the first and second layers of passive variable resistance memory cells. The method then forms a second lower electrode layer above the second dielectric layer and a second memory layer above the second lower electrode layer. The method also forms a second upper electrode layer above the second memory layer.

In still another example, the method may also pattern the upper electrode layer to form at least one extend contact pad, which is electrically connected to the processor logic through at least one of the plurality of vias.

Among other advantages, the method for making the integrated circuit with vertically integrated passive variable resistance memory provides a simple and inexpensive way to integrate the next generation of FRT (e.g., passive variable resistance memory) with the existing processors to improve the processor performance. This method allows for the FRT processing to be done after the CMOS logic devices (e.g., processor logic and/or memory control logic) are fabricated to avoid integration problems and to separate the FRT material contamination from the CMOS logic devices. In addition, compared with known integration solutions, the vertically integrated passive variable resistance memory eliminates any die area increase and enables faster memory access by both reducing the connection distance and allowing for the increased number of parallel connections. Moreover, the method for making the integrated circuit with vertically integrated passive variable resistance memory provides flexibility for adopting various types of passive variable resistance memory such as but not limited to memristor, phase-change memory, or magnetoresistive memory. Other advantages will be recognized by those of ordinary skill in the art.

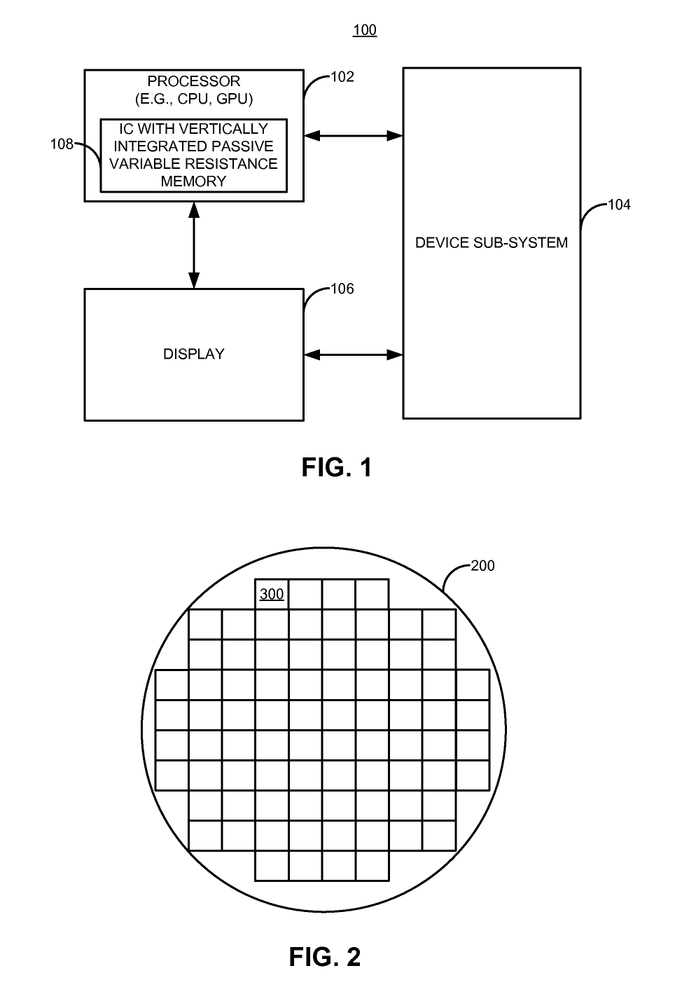

FIG. 1 illustrates one example of an apparatus 100 including a processor 102 with vertically integrated passive variable resistance memory. The apparatus 100 may be any suitable device, for example, a laptop computer, desktop computer, media center, handheld device (e.g., mobile or smart phone, tablet, etc.), Blu-ray™ player, gaming console, set top box, printer, or any other suitable device. The apparatus 100 may also include a device sub-system 104 and/or a display 106 that are operatively coupled to the processor 102. It is understood, however, that any other suitable component may also be included in the apparatus 100. The processor 102 may be a host central processing unit (CPU) having one or multiple cores, a discrete graphic processing unit (GPU), an integrated GPU, a general processor (e.g., APU, accelerated processing unit; GPGPU, general-purpose computing on GPU), or any other suitable processor. In this example, the processor 102 includes an integrated circuit 108 with vertically integrated passive variable resistance memory serving as, for example, processor registers, on-die cache memory (e.g., L1, L2, and L3 caches), and/or main memory. The processor 102 may include any other suitable logic and circuit on the same integrated circuit die of the passive variable resistance memory or on a different integrated circuit die, and may also include any suitable packaging component.

FIG. 2 illustrates one example of a wafer 200 that includes a plurality of integrated circuit dies 300. The integrated circuit die 300 may form the integrated circuit 108 with vertically integrated passive variable resistance memory as part of the processor 102 as shown in FIG. 1. The plurality of integrated circuit dies 300 may be tested at the wafer level and then cut out of the wafer 200 after testing if necessary. It will be recognized that any suitable number of integrated circuit dies 300 and interconnections may be employed on the wafer 200.

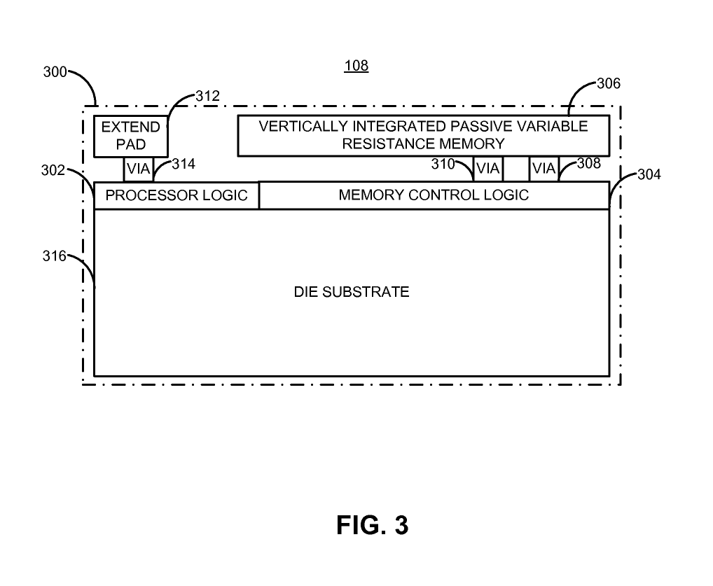

FIG. 3 illustrates the cross-sectional view of one example of an integrated circuit. In this example, the integrated circuit 108 may include a layer of single-crystal silicon as the integrated circuit die substrate 316 of the integrated circuit die 300. In other examples, the integrated circuit die substrate 316 may be germanium, silicon on insulator (SOI) such as SiO₂ based SOI and silicon on sapphire, compound semiconductor such as GaAs, GaN to name a few, organic semiconductor, or any other suitable semiconductor substrate. The integrated circuit 108 includes processor logic 302 and memory control logic 304 formed on the integrated circuit die 300. The processor logic 302 and memory control logic 304 are operatively coupled to each other in this example. In this example, the logic 302, 304 is formed directly on top of the integrated circuit die substrate 316 without any intervening structures or layers in between them. However, it is understood that in other examples, intervening structures or layers may be formed between the logic 302, 304 and the integrated circuit die substrate 316. The processor logic 302 and memory control logic 304 include active semiconductor devices that are capable of electrically controlling electron flow, such as but not limited to bipolar or field effect transistors (FET), semiconductor controlled rectifiers (SCR), or triode for alternating current (TRIAC), to name a few. The processor logic 302 and memory control logic 304 may also include passive devices that are incapable of controlling current by means of another electrical signal, such as but not limited to resistors, capacitors, inductors, transformers, transmission lines, or any other suitable passive device. In one example, the processor logic 302 and memory control logic 304 mainly include active CMOS circuits and passive devices (e.g. metal interconnections) constructed in the surface of a thin single-crystal silicon layer. As noted above. the processor logic 302 may include at least one of a CPU having one or multiple cores, a discrete or integrated GPU, an APU, a GPGPU, and any other suitable logic. It is understood, however, that in other examples, the integrated circuit 108 may not include the processor logic 302. Instead, the processor 102 may include another integrated circuit that has processor logic operatively coupled to the memory control logic 304 on the integrated circuit 108 through wire bonding or any other suitable connections known in the art.

The integrated circuit 108 also includes passive variable resistance memory 306 having a plurality of passive variable resistance memory cells disposed above the memory control logic 304. That is, in this example, the passive variable resistance memory 306 is vertically integrated with fabricated processor logic 302 and memory control logic 304. The passive variable resistance memory 306 may include passive variable resistance devices such as but not limited to memristors, phase-change memory, magnetoresistive memory, or any other suitable passive variable resistance memory. For example, memristor is essentially a two-terminal variable resistor, with resistance dependent upon the amount of charge that passed between the terminals. As to phase-change memory, it comprises a heating resistor and chalcogenide between electrodes that can change its resistivity in response to thermal heating caused by current injection. For magnetoresistive memory, it stores information in the form of a magnetic tunnel junction, which separates two ferromagnetic materials with a layer of a thin insulating material. The storage state of each magnetoresistive memory cell changes when one layer switches to align with or oppose the direction of its counterpart layer, which then affects the junction's resistance.

In this example, the passive variable resistance memory 306 serves as on-die memory for the processor logic 302, such as processor registers, on-die cache memory (e.g., L1, L2, and L3 caches), or main memory. Each memory cell of the passive variable resistance memory 306 is electrically connected to the memory control logic 304 through at least one of a plurality of vias 308, 310. The memory control logic 304 controls the operation (e.g., write/read) of the passive variable resistance memory 306 by control signals (e.g., voltage/current) through the vias 308, 310. Although two vias 308, 310 between the passive variable resistance memory 306 and the memory control logic 304 are shown in FIG. 3, it is understood, however, that the actual number of vias may vary. The processor logic 302 may be electrically connected to at least one extend contact pad 312 through at least one via 314. The extend contact pad 312 serves as an interface for transmitting and receiving supply/signal outside the integrated circuit 108 by soldering, wire bonding, flip chip mounting, probe needles, or any other suitable packaging method.

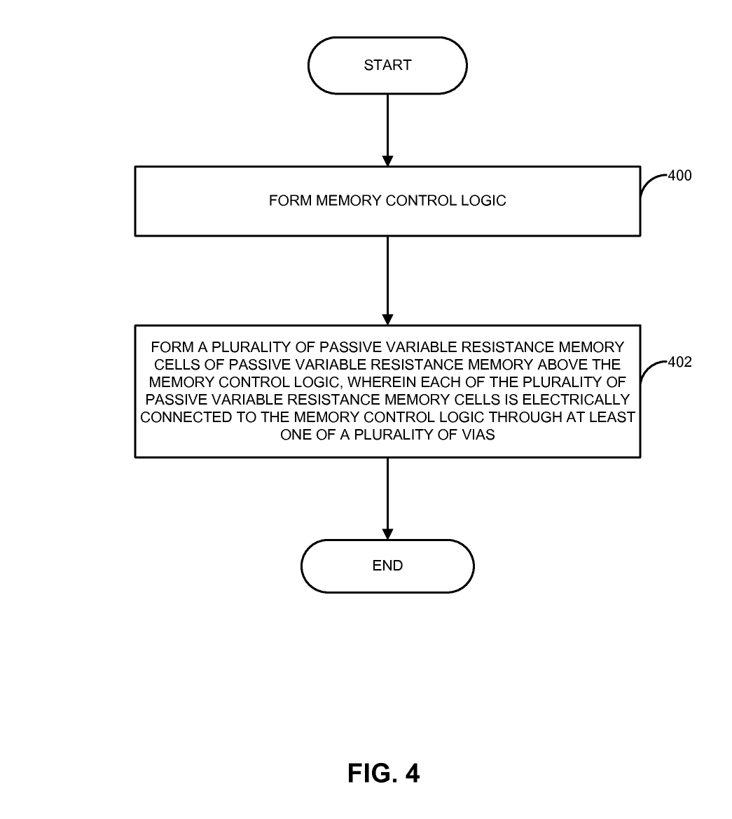

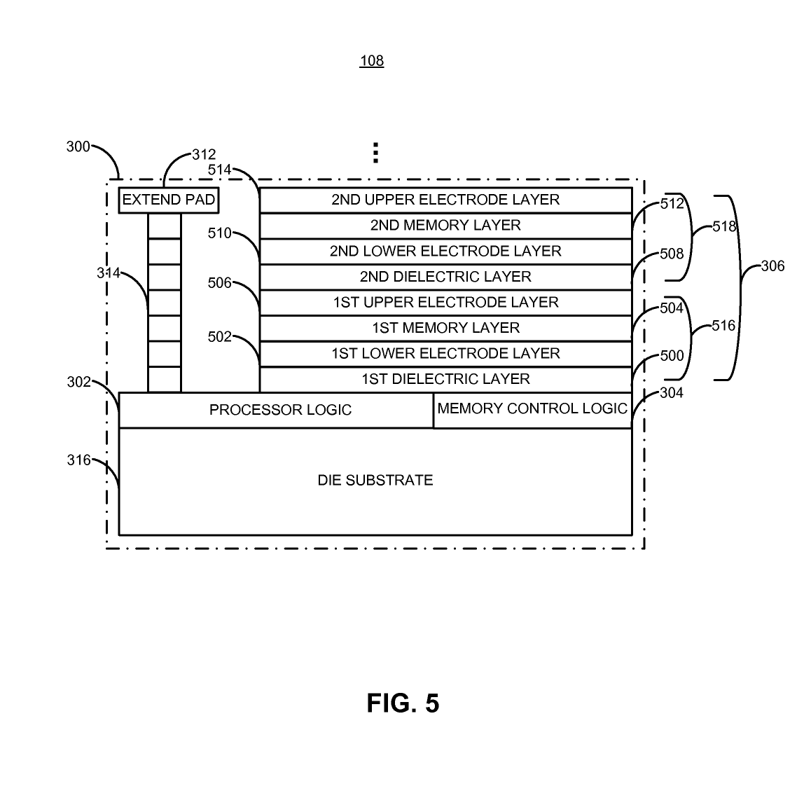

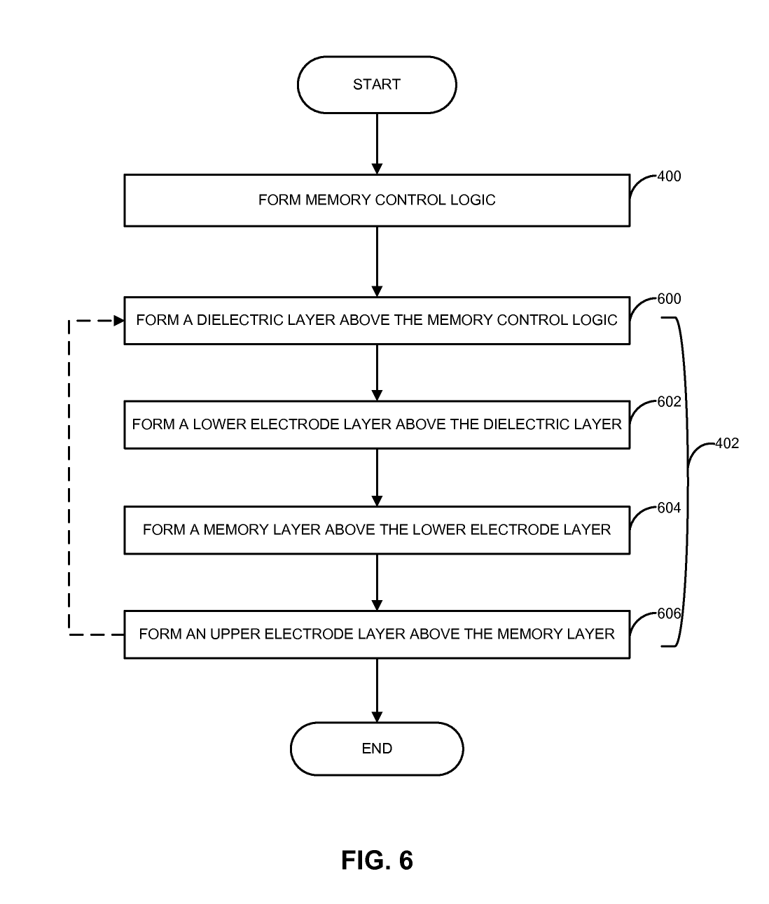

FIG. 4 illustrates one example of a method for making an integrated circuit with vertically integrated passive variable resistance memory. It will be described with reference to FIG. 3. However, any suitable structure may be employed. In operation, memory control logic 304 is formed on the integrated circuit die 300 at block 400. In one example, the memory control logic 304 is fabricated using standard very-large-scale integration (VLSI) CMOS fabrication process on a single-crystal silicon die. Proceeding to block 402, a plurality of memory cells of the passive variable resistance memory 306 are formed above the memory control logic 304. Each memory cell of the passive variable resistance memory 306 is electrically connected to the memory control logic 304 through at least one of the plurality of vias 308, 310. Block 402 is further illustrated in FIGS. 5 and 6.

Referring to FIG. 5, the passive variable resistance memory 306 may include multiple layers of passive variable resistance memory cells. For example, the first layer 516 of the passive variable resistance memory cells includes a first dielectric layer 500, a first lower electrode layer 502, a first memory layer 504, and a first upper electrode layer 506. The second layer 518 is stacked above the first layer 516 of passive variable resistance memory cells and includes a second dielectric layer 508, a second lower electrode layer 510, a second memory layer 512, and a second upper electrode layer 514. Although not shown in FIG. 5, it is understood, however, that more layers may be formed above the second layer 518 of passive variable resistance memory cells. In this way, the storage size of the passive variable resistance memory 306 may be increased without increasing the die area.

Since more layers are formed above the existing memory control logic 304 and processor logic 302 to build the passive variable resistance memory 306, one or more extend contact pads 312 may be formed on the same layer of the uppermost metal electrode of the passive variable resistance memory 306. In one example as shown in FIG. 5, at least one extend contact pad 312 is formed on the second upper electrode layer 514 as well and is electrically connected to the existing contact pad of the processor logic 302 through the via 314, which is formed through all the layers of the passive variable resistance memory 306. If one or more extend contact pads 312 are formed, they replace the existing contact pads of the processor logic 302 as an interface for transmitting and receiving supply/signal outside the integrated circuit 108 by soldering, wire bonding, flip chip mounting, probe needles, or any other suitable packaging method.

Referring now to FIG. 6, after forming the memory control logic 304 on the integrated circuit die 300 at block 400, the dielectric layer 500 is formed above the memory control logic 304 at block 600. The dielectric layer 500 may be formed using any suitable dielectric material, for example, low-k dielectric materials such as various types of SiO₂, or high-k dielectric materials, by thin-film deposition techniques such as chemical vapor deposition (CVD), thermal evaporation, sputtering, molecular beam epitaxy (MBE), or spin-coating. The dielectric layer 500 may be patterned to form the vias 308, 310, 314 using conventional techniques such as photolithography or electron beam lithography, or by more advanced techniques, such as imprint lithography.

At block 602, the lower electrode layer 502 is formed above the dielectric layer 500. The lower electrode layer 502 may be formed using any suitable metal or semiconductor materials such as but not limited to platinum, copper, gold, aluminum, titanium, iridium, iridium oxide, ruthenium, or silver, by thin-film deposition techniques such as CVD, thermal evaporation, sputtering, MBE, or electroplating. Proceeding to block 604, the memory layer 504 is formed above the lower electrode layer 502. The memory layer 504 is formed by thin-film deposition techniques such as CVD, thermal evaporation, sputtering, MBE, electroplating, spin-coating, or any other suitable techniques. The material of the memory layer 504 may be any suitable variable resistance material that is capable of storing state by resistance. Depending on the specific type of passive variable resistance memory 306, the material of the memory layer 504 may include, for example, one or more thin-film oxides (e.g., TiO₂, SiO₂, NiO, CeO₂, VO₂, V₂O₅, Nb₂O₅, Ti₂O₃, WO₃, Ta₂O₅, ZrO₂, IZO, ITO, etc.) for memristors, chalcogenide for phase-change memory, and ferromagnetic materials (e.g., CoFeB incorporated in MgO) for magnetoresistive memory. Proceeding to block 606, the upper electrode layer 506 is formed above the memory layer 504. The material and fabrication technique of the upper electrode layer 506 is for example the same as of the lower electrode layer 502. However, it is understood that different materials and/or thin-film deposition techniques may be applied to the lower and upper electrode layers 502, 506 if necessary. As discussed previously, blocks 600-606 may be repeated to form multiple layers of passive variable resistance memory cells in the vertical direction to increase the storage size of the passive variable resistance memory 306 without increasing the die area. The uppermost electrode layer (e.g., the second upper electrode layer 514 in FIG. 5) of the passive variable resistance memory 306 may also be patterned to form the extend contact pads 312 for the processor logic 302 using conventional techniques such as photolithography or electron beam lithography, or by more advanced techniques, such as imprint lithography. Although the processing blocks illustrated in FIG. 6 are illustrated in a particular order, those having ordinary skill in the art will appreciate that the processing can be performed in different orders.

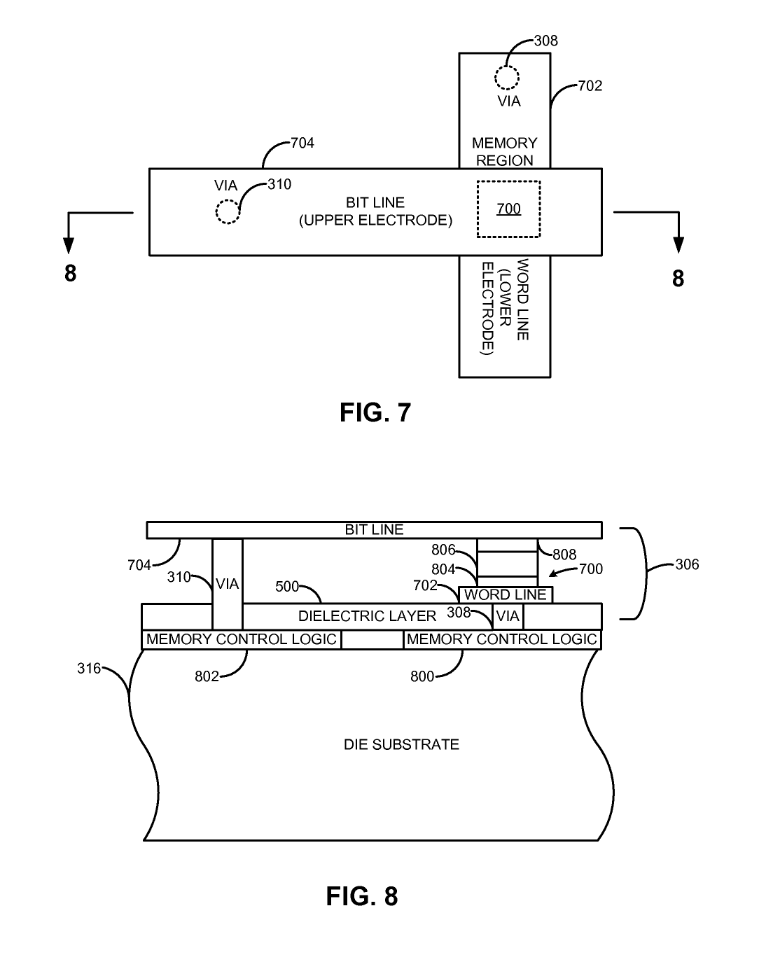

FIGS. 7 and 8 illustrate an example of a memristor as one vertically integrated passive variable resistance memory cell of an integrated circuit according to one embodiment of the disclosure.

It is known in the art that memory may be implemented by an array of memory cells. Each memory cell of the array includes a memory region as a place to store state, which represents one bit of information. As shown in FIGS. 7 and 8, in order to access each memory cell, the array of memory is organized by rows and columns, and the intersection point of each row-column pair is a memory region 700. The rows are also called word lines 702, whereas the columns are named bit lines 704. The word lines 702 and bit lines 704 are electrically connected to the memory control logic 800, 802 through the vias 308, 310, respectively, so that the operation (e.g., write/read) of each memory region 700 can be controlled by the memory control logic 800, 802. In this example, the lower electrode layer 502 is patterned as the word line 702, and part of the memory control logic 800 is electrically connected to the word line 702 through at least one via 308 to drive the word line 702 by applying a current/voltage signal to the word line 702. Likewise, the upper electrode layer 506 is patterned as the bit line 704, and another part of the memory control logic 802 is electrically connected to the bit line 704 through at least another via 310 to drive the bit line 704 by applying another current/voltage signal to the bit line 704. In other examples, it is understood, however, that the lower electrode layer 502 may be patterned as the bit line 704 while the upper electrode layer 506 may be patterned as the word line 702 if desired.

In this example embodiment, each passive variable resistance memory cell (e.g. one bit) may be a memristor of any suitable design. Since a memristor includes a memory region 700 (e.g., a layer of TiO₂) between two metal electrodes (e.g., platinum wires), memristors could be accessed in a crosspoint array style (i.e., crossed-wire pairs) with alternating current to non-destructively read out the resistance of each memory cell. A crosspoint array is an array of memory regions 700 that can connect each wire in one set of parallel wires (word lines 702) to every member of a second set of parallel wires (bit lines 704) that intersects the first set (usually the two sets of wires are perpendicular to each other, but this is not a necessary condition). In other words, each memory cell may be, for example, part of a crosspoint array. The memristor disclosed herein may be fabricated using a wide range of material deposition and processing techniques. One example is disclosed in corresponding U.S. Patent Application Publication No. 2008/0090337, having a title “ELECTRICALLY ACTUATED SWITCH”, which is incorporated herein by reference.

In this example, first, a lower electrode (e.g., word line 702) is fabricated using conventional techniques such as photolithography or electron beam lithography, or by more advanced techniques, such as imprint lithography. This may be, for example, the bottom wire (word line 702) of a crossed-wire pair as shown in FIG. 7. The material of the lower electrode may be either metal or semiconductor material, for example, platinum.

In this example, the next component of the memristor to be fabricated is the non-covalent interface layer 804, and may be omitted if greater mechanical strength is required, at the expense of slower switching at higher applied voltages. In this case, a layer of some inert material is deposited. This could be a molecular monolayer formed by a Langmuir-Blodgett (LB) process or it could be a self-assembled monolayer (SAM). In general, this interface layer 804 may form only weak van der Waals-type bonds to the lower electrode (e.g., word line 702) and the primary layer 806 of the memory region 700. Alternatively, this interface layer 804 may be a thin layer of ice deposited onto a cooled integrated circuit die substrate. The material to form the ice may be an inert gas such as argon, or it could be a species such as CO₂. In this case, the ice is a sacrificial layer that prevents strong chemical bonding between the lower electrode (e.g., word line 702) and the primary layer 806 of the memory region 700, and is lost from the system by heating later the integrated circuit die substrate in the processing sequence to sublime the ice away. One skilled in this art can easily conceive of other ways to form weakly bonded interfaces between the lower electrode (e.g., word line 702) and the primary layer 806 of the memory region 700.

Next, the material for the primary layer 806 of the memory region 700 is deposited. This can be done by a wide variety of conventional physical and chemical techniques, including evaporation from a Knudsen cell, electron beam evaporation from a crucible, sputtering from a target, or various forms of chemical vapor or beam growth from reactive precursors. The film may be in the range from 1 to 30 nanometers (nm) thick, and it may be grown to be free of dopants. Depending on the thickness of the primary layer 806, it may be nanocrystalline, nanoporous, or amorphous in order to increase the speed with which ions can drift in the material to achieve doping by ion injection or undoping by ion ejection from the primary layer 806. Appropriate growth conditions, such as deposition speed or temperature, may be chosen to achieve the chemical composition and local atomic structure desired for this initially insulating or low conductivity primary layer 806.

The next layer is the dopant source layer (i.e., secondary layer 808) for the primary layer 806, which may also be deposited by any of the techniques mentioned above. This material is chosen to provide the appropriate doping species for the primary layer 806. This secondary layer 808 is chosen to be chemically compatible with the primary layer 806, e.g., the two materials should not react chemically and irreversibly with each other to form a third material. One example of a pair of materials that can be used as the primary and secondary layers 806, 808 is TiO₂ and TiO₂₋ₓ, respectively. TiO₂ is a semiconductor with an approximately 3.2 eV bandgap. It is also a weak ionic conductor. A thin film of TiO₂ creates the tunnel barrier, and the TiO₂₋ₓ forms an ideal source of oxygen vacancies to dope the TiO₂ and make it conductive.

In this example, finally, an upper electrode (e.g., bit line 704) is fabricated above the secondary layer 808 of the memory region 700, in a manner similar to which the lower electrode (e.g., word lines 702) was created. This may be, for example, the top wire (bit line 704) of the crossed-wire pair as shown in FIG. 7. The material of the upper electrode (e.g., bit line 704) may be either metal or semiconductor material, for example, platinum. If the memory cell is in a crossbar style as shown in FIG. 7, an etching process may be necessary to remove the deposited memory region material that is not under the upper electrode (e.g., bit line 704) in order to isolate the memory cell. It is understood, however, that any other suitable material deposition and processing techniques may be used to fabricate memristors for the passive variable resistance memory 306.

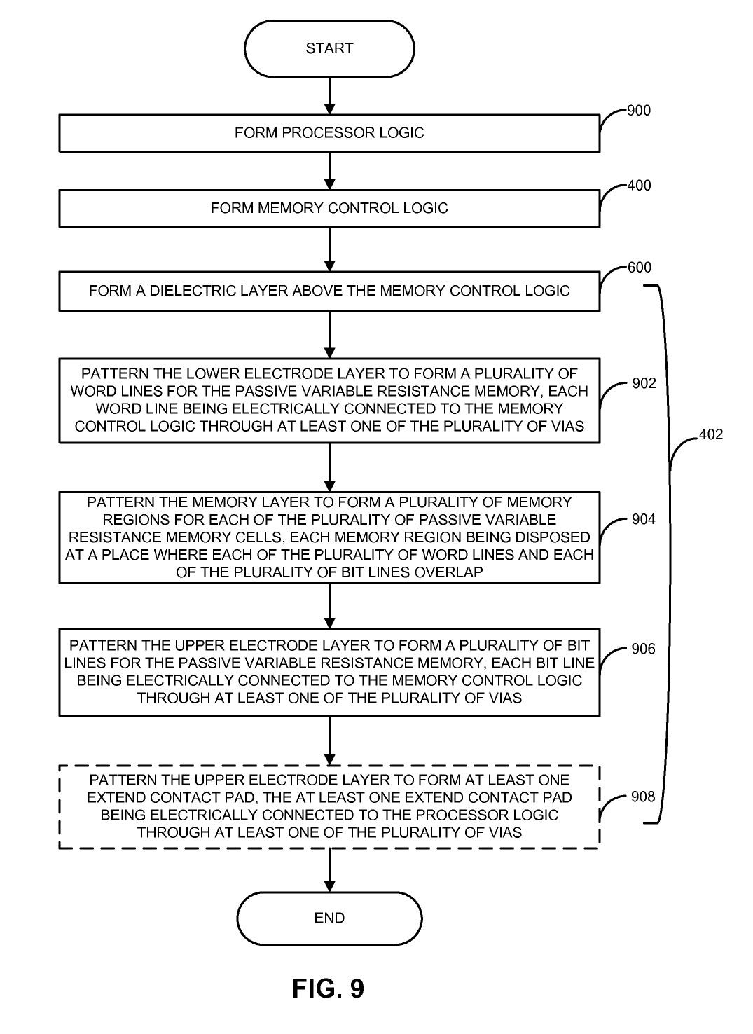

FIG. 9 illustrates one example of a method for making an integrated circuit with vertically integrated passive variable resistance memory. It will be described with reference to FIGS. 5, 7, and 8. However, any suitable structure may be employed. In operation, after forming the processor logic 302 at block 900 and memory control logic 304 at block 400, the dielectric layer 500 is formed above the memory control logic 304, 800, 802 and the processor logic 302 at block 600. The dielectric layer 500 may be patterned to form the vias 308, 310, 314 using conventional techniques such as photolithography or electron beam lithography, or by more advanced techniques, such as imprint lithography.

Proceeding to block 902, the lower electrode layer 502 is patterned to form a plurality of word lines 702 for the passive variable resistance memory 306, wherein each word line 702 is electrically connected to the memory control logic 800 through at least one of the plurality of vias 308. The word line 702 may be the bottom wire of the crossed-wire pair as shown in FIG. 7. As mentioned previously, the word line 702 may be fabricated using conventional techniques such as photolithography or electron beam lithography, or by more advanced techniques, such as imprint lithography. At block 904, the memory layer 504 is patterned to form a plurality of memory regions 700 for each memory cell of the passive variable resistance memory 306 using conventional techniques such as photolithography or electron beam lithography, or by more advanced techniques, such as imprint lithography. Each memory region 700 is, for example, an intersection of the crossed-wire pair that is disposed at a place where each word line 702 and bit line 704 overlap. As mentioned previously, the memory region 700 may include one or more thin-film oxide layers deposited by any known techniques in the case of memristor or may include a chalcogenide layer in the case of phase-change memory. At block 906, the upper electrode layer 506 is patterned to form a plurality of bit lines 704 for the passive variable resistance memory 306 using conventional techniques such as photolithography or electron beam lithography, or by more advanced techniques, such as imprint lithography, wherein each bit line 704 is electrically connected to the memory control logic 802 through at least one of the plurality of vias 310. The bit line 704 may be the top wire of the crossed-wire pair as shown in FIG. 7, and fabricated using the same material and technique for the word line 702. Additionally or optionally, at block 908, the upper electrode layer 506 may also be patterned to form at least one extend contact pad 312, which is electrically connected to the processor logic 302 (e.g., connected to an existing contact pad of the processor logic 302) through at least one of the plurality of vias 314. Although the processing blocks illustrated in FIG. 9 are illustrated in a particular order, those having ordinary skill in the art will appreciate that the processing can be performed in different orders.

Also, integrated circuit design systems (e.g., work stations) are known that create wafers with integrated circuits based on executable instructions stored on a computer readable medium such as but not limited to CDROM, RAM, other forms of ROM, hard drives, distributed memory, etc. The instructions may be represented by any suitable language such as but not limited to hardware descriptor language (HDL), Verilog or other suitable language. As such, the logic and circuits described herein may also be produced as integrated circuits by such systems using the computer readable medium with instructions stored therein. For example, an integrated circuit with the aforedescribed logic and structure may be created using such integrated circuit fabrication systems. The computer readable medium stores instructions executable by one or more integrated circuit design systems that causes the one or more integrated circuit design systems to design an integrated circuit. The designed integrated circuit includes processor logic and at least one extend contact pad electrically connected to the processor logic through at least one of a plurality of vias. The designed integrated circuit also includes memory control logic operatively coupled to the processor logic and a plurality of passive variable resistance memory cells of passive variable resistance memory disposed above the memory control logic. Each of the plurality of passive variable resistance memory cells is electrically connected to the memory control logic through at least one of the plurality of vias. The designed integrated circuit may also include any other structure as disclosed herein.

Among other advantages, the method for making the integrated circuit with vertically integrated passive variable resistance memory provides a simple and inexpensive way to integrate the next generation of FRT (e.g., passive variable resistance memory) with the existing processors to improve the processor performance. This method allows for the FRT processing to be done after the CMOS logic devices (e.g., processor logic and/or memory control logic) are fabricated to avoid integration problems and to separate the FRT material contamination from the CMOS logic devices. In addition, compared with known integration solutions, the vertically integrated passive variable resistance memory eliminates any die area increase and enables faster memory access by both reducing the connection distance and allowing for the increased number of parallel connections. Moreover, the method for making the integrated circuit with vertically integrated passive variable resistance memory provides flexibility for adopting various types of passive variable resistance memory such as but not limited to memristor, phase-change memory, or magnetoresistive memory. Other advantages will be recognized by those of ordinary skill in the art.

The above detailed description of the invention and the examples described therein have been presented for the purposes of illustration and description only and not by limitation. It is therefore contemplated that the present invention cover any and all modifications, variations or equivalents that fall within the spirit and scope of the basic underlying principles disclosed above and claimed herein.

What is claimed is:

1. A method for making an integrated circuit comprising:
forming memory control logic; and
forming a plurality of passive variable resistance memory cells of passive variable resistance memory above the memory control logic, wherein each of the plurality of passive variable resistance memory cells is electrically connected to the memory control logic through at least one of a plurality of vertical interconnect accesses (vias).

2. The method of claim 1, wherein forming the plurality of passive variable resistance memory cells comprises:
forming a dielectric layer above the memory control logic;
forming a lower electrode layer above the dielectric layer;
forming a memory layer above the lower electrode layer; and
forming an upper electrode layer above the memory layer.

3. The method of claim 2, wherein forming the lower electrode layer comprises patterning the lower electrode layer to form a plurality of word lines for the passive variable resistance memory, each word line being electrically connected to the memory control logic through at least one of the plurality of vias.

4. The method of claim 3, wherein forming the upper electrode layer comprises patterning the upper electrode layer to form a plurality of bit lines for the passive variable resistance memory, each bit line being electrically connected to the memory control logic through at least one of the plurality of vias.

5. The method of claim 4, wherein forming the memory layer comprises patterning the memory layer to form a plurality of memory regions for each of the plurality of passive variable resistance memory cells, each memory region being disposed at a place where each of the plurality of word lines and each of the plurality of bit lines overlap.

6. The method of claim 4 further comprising forming processor logic operatively coupled to the memory control logic; and wherein forming the upper electrode layer further comprises patterning the upper electrode layer to form at least one extend contact pad, the at least one extend contact pad being electrically connected to the processor logic through at least one of the plurality of vias.

7. The method of claim 2, wherein the dielectric layer, the lower electrode layer, the memory layer, and the upper electrode layer are the first dielectric layer, the first lower electrode layer, the first memory layer, and the first upper electrode layer, respectively, of a first layer of the passive variable resistance memory cells; and wherein forming the plurality of passive variable resistance memory cells further comprises forming a second layer of the passive variable resistance memory cells comprising:
forming a second dielectric layer above the first upper electrode layer;
forming a second lower electrode layer above the second dielectric layer;
forming a second memory layer above the second lower electrode layer; and
forming a second upper electrode layer above the second memory layer.

8. The method of claim 1, wherein each of the plurality of passive variable resistance memory cells is a memristor.

9. The method claim 1, wherein each of the plurality of passive variable resistance memory cells is part of a crosspoint array.

10. An integrated circuit comprising:
memory control logic; and
a plurality of passive variable resistance memory cells of passive variable resistance memory disposed above the memory control logic, wherein each of the plurality of passive variable resistance memory cells is electrically connected to the memory control logic through at least one of a plurality of vias.

11. The integrated circuit of claim 10, wherein the passive variable resistance memory comprises a plurality of word lines, each word line being electrically connected to the memory control logic through at least one of the plurality of vias.

12. The integrated circuit of claim 11, wherein the passive variable resistance memory further comprises a plurality of bit lines, each bit line being electrically connected to the memory control logic through at least one of the plurality of vias.

13. The integrated circuit of claim 12, wherein the passive variable resistance memory further comprises a plurality of memory regions for each of the plurality of passive variable resistance memory cells, each memory region being disposed at a place where each of the plurality of word lines and each of the plurality of bit lines overlap.

14. The integrated circuit of claim 13, wherein a resistance of each memory region changes based on a first electrical signal applied to the plurality of word lines and a second electrical signal applied to the plurality of bit lines by the memory control logic through the plurality of vias.

15. The integrated circuit of claim 10 further comprising:
processor logic operatively coupled to the memory control logic; and
at least one extend contact pad electrically connected to the processor logic through at least one of the plurality of vias.

16. The integrated circuit of claim 10, wherein the passive variable resistance memory comprises a plurality of layers of the passive variable resistance memory cells, each layer of the passive variable resistance memory cells comprising a dielectric layer, a lower electrode layer, a memory layer, and an upper electrode layer.

17. The integrated circuit of claim 10, wherein each of the plurality of passive variable resistance memory cells is a memristor.

18. The integrated circuit of claim 10, wherein each of the plurality of passive variable resistance memory cells is part of a crosspoint array.

19. The integrated circuit of claim 15, wherein the processor logic comprises at least one of a graphic processing unit, a central processing unit, and an accelerated processing unit.

20. An apparatus comprising:
a processor comprising:
processor logic;
at least one extend contact pad electrically connected to the processor logic through at least one of a plurality of vias;
memory control logic operatively coupled to the processor logic; and
a plurality of passive variable resistance memory cells of passive variable resistance memory disposed above the memory control logic, wherein each of the plurality of passive variable resistance memory cells is electrically connected to the memory control logic through at least one of the plurality of vias; and
a display operatively coupled to the processor.

21. A computer readable medium storing instructions executable by one or more integrated circuit design systems that causes the one or more integrated circuit design systems to design an integrated circuit comprising:
processor logic;
at least one extend contact pad electrically connected to the processor logic through at least one of a plurality of vias;
memory control logic operatively coupled to the processor logic; and
a plurality of passive variable resistance memory cells of passive variable resistance memory disposed above the memory control logic, wherein each of the plurality of passive variable resistance memory cells is electrically connected to the memory control logic through at least one of the plurality of vias.

22. An integrated circuit product made by a process of:
forming memory control logic; and
forming a plurality of passive variable resistance memory cells of passive variable resistance memory above the memory control logic, wherein each of the plurality of passive variable resistance memory cells is electrically connected to the memory control logic through at least one of a plurality of vias.
